(19) United States
(12) Patent Application Publication
(10) Pub. No.: US 2008/0083970 A1
(43) Pub. Date: Apr. 10, 2008

(54) Method and materials for growing III-nitride semiconductor compounds containing aluminum

(76) Inventors: Derrick S. Kamber, Goleta, CA (US); Benjamin A. Haskell, Santa Barbara, CA (US); Shuji Nakamura, Santa Barbara, CA (US); Tadao Hashimoto, Goleta, CA (US)

Correspondence Address: GATES & COOPER LLP;HOWARD HUGHES CENTER, 6701 CENTER DRIVE WEST, SUITE 1050, LOS ANGELES, CA, 90045, US

(21) Appl. No.: 11/801,053

(22) Filed: May 8, 2007

Related U.S. Application Data
(60) Provisional application No. 60/798,905, filed on May 8, 2006.

(51) Int. Cl. H01L 21/36; H01L 29/20

(52) U.S. Cl. 257/615; 438/508; 257/E29.089; 257/E21.461

(57) ABSTRACT

A method for growing III-nitride films containing aluminum using Hydride Vapor Phase Epitaxy (HVPE) is disclosed, and comprises using corrosion-resistant materials in an HVPE system, the region of the HVPE system containing the corrosion-resistant materials being an area that contacts an aluminum halide, heating a source zone with an aluminum-containing source above a predetermined temperature, and growing the III-nitride film containing aluminum within the HVPE system containing the corrosion-resistant material.

### CROSS-REFERENCE TO RELATED APPLICATIONS

This application claims the benefit under 35 U.S.C. §119(e) of the following co-pending and commonly-assigned U.S. patent application:

U.S. Provisional Patent Application Ser. No. 60/798,905, filed on May 8, 2006, by Derrick S. Kamber, Benjamin A. Haskell, Shuji Nakamura, and Tadao Hashimoto, entitled “METHOD AND MATERIALS FOR GROWING III-V NITRIDE SEMICONDUCTOR COMPOUNDS CONTAINING ALUMINUM,” attorneys docket number 30794.181-US-P1 (2006-489-1);

which application is incorporated by reference herein.

### STATEMENT REGARDING FEDERALLY SPONSORED RESEARCH AND DEVELOPMENT

This invention was made with Government support under Grant No. 02-002 awarded by DARPA. The Government has certain rights in this invention.

### BACKGROUND OF THE INVENTION

1. Field of the Invention

The invention is related to a method and materials for growing III-nitride semiconductor compounds containing aluminum.

2. Description of the Related Art

(Note: This application references a number of different publications as indicated throughout the specification by one or more reference numbers within brackets, e.g., [Ref. x]. A list of these different publications ordered according to these reference numbers can be found below in the section entitled “References.” Each of these publications is incorporated by reference herein.)

Aluminum (Al)-containing III-V compound semiconductors are of significant value since they are used in the fabrication of many optoelectronic and electronic devices. Of particular interest are Al-containing III-V nitrides, also referred to as III-nitrides or III-nitride semiconductors. Generally speaking, a III-nitride semiconductor is one for which its chemical formula is (AlₓB_{y}In_{z}Ga_{1-x-y-z})N, in which 0≦x≦1, 0≦y≦1, 0≦z≦1, and 0≦x+y+z≦1. The III-nitride semiconductors, including aluminum nitride (AlN), gallium nitride (GaN), indium nitride (InN), hexagonal boron nitride (BN), and their alloys, have gained considerable interest in the past two decades due to the potential of these materials to span energy bandgaps from 0.9 eV to 6.2 eV. These alloys have direct bandgaps, making them extremely useful in optoelectronics as both optical detectors and light emitters. Additionally, the nitrides have also been used to fabricate high-power, high-temperature, and high-frequency electronic devices due to their high critical breakdown fields and superior electron transport properties. Though the present invention applies to any AlBInGaN compound containing a non-negligible amount of Al, for simplicity the remainder of the discussion below will focus on alloys containing predominantly aluminum and gallium (AlGaN).

The addition of aluminum to III-nitrides serves to increase the bandgap of the material relative to that of pure indium nitride, pure gallium nitride, or indium gallium nitride compounds. Aluminum nitride has a large direct bandgap of 6.2 eV at room temperature, and this enables alloys containing gallium (AlGaN) to have tunable bandgaps from 3.4 eV to 6.2 eV. Changing the relative aluminum and gallium compositions in the material alters the bandgap. This control over the bandgap of the material permits device fabrication enabling emission and detection of ultraviolet (UV) and visible radiation over this entire spectral range.

Although AlGaN-based devices have been successfully fabricated, to produce improved high-power, high-frequency electronic and ultraviolet optoelectronic devices, a suitable substrate is required to enhance the performance and cost effectiveness of such devices. Currently, there are no readily available, inexpensive, high-quality substrate materials for the III-nitride semiconductors. Foreign substrates, therefore, have to be used for heteroepitaxial growth, specifically sapphire or silicon carbide, and the lattice mismatch between the growing film and the substrate leads to stress in the film and often cracking. The large lattice mismatch in heteroepitaxy (i.e. the growth of AlGaN on a foreign substrate) also typically results in a high concentration of threading dislocations (microscopic crystallographic line defects), which form at the substrate-nitride interface and generally propagate upward through the growing film. The dislocation density for AlN films grown on foreign substrates is typically 10⁹ cm⁻² or higher. These defects significantly degrade device performance when they propagate into the active regions of devices.

To counteract these damaging effects, it is necessary to grow electronic and optoelectronic III-nitride devices on substrates with closely matched lattice constants to the films that are to be epitaxially grown. One means of accomplishing this goal is to deposit a thick film of an Al-containing III-nitride material directly on the chosen substrate prior to device growth. A variety of epitaxial techniques have been explored to deposit this thick layer, including molecular beam epitaxy (MBE), metalorganic chemical vapor deposition (MOCVD), and hydride (or halide) vapor phase epitaxy (HVPE). The low growth rates of MBE and MOCVD, however, make these techniques unsuitable for the growth of films of approximately 3 μm or thicker.

HVPE has emerged as the method of choice for the growth of thick films of III-V compounds. HVPE is a vapor-phase growth technique that utilizes gaseous transport of reactive species to the substrate for chemical reaction and film growth at high growth rates, typically in excess of 50 μm/hr. These high growth rates enable the production of thick III-nitride layers on foreign substrates, and these thick layers can optionally be removed from the foreign substrate to produce free-standing layers. In general, the HVPE process involves the reaction of one or more metallic halides with an anionic hydride. For the growth of III-nitride semiconductors, the metallic halide is the Group III source, while the hydride, which is ammonia (NH₃), is the group V source. These two source materials are generally separately transported to the vicinity of the substrate with a carrier gas, typically nitrogen (N₂), hydrogen (H₂), helium (He), or argon (Ar), where they react to form the film.

Despite the advantages HVPE presents for the growth of III-nitride compound semiconductors, the growth of Al-containing materials by this method has proven difficult due to the formation of the aluminum monohalide (e.g., AlCl, AlI or AlBr) in the source zone. At typical III-nitride growth temperatures (800° C. and hotter), the aluminum monohalide formed in the source zone readily chemically attacks quartz (SiO₂), which is the principal enclosure material employed in HVPE growth chambers. This reaction chemically degrades the quartz, causing oxygen and silicon contamination in the growing film. While the process is not completely understood, it is believed that reduction occurs through the following substitutional reaction:

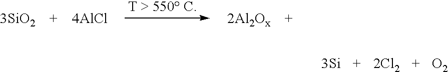

where the Al₂Oₓ indicates a sub-oxide of Al. This corrosion process introduces significant impurities into the growing film, which deteriorate the film quality, resulting in poor epitaxial growth of Al-containing III-nitrides.

The production of the aluminum monohalide in the source zone has frustrated previous attempts to grow Al-containing III-nitrides by HVPE. The limited attempts to grow such materials have resulted in reactor deterioration and poor film quality, and so researchers have been forced to develop alternative techniques for the deposition of Al-containing III-nitrides. Kumagai et al. have developed a patent-pending process wherein the source zone temperature is maintained at approximately 500° C. in order to react HCl gas with metallic Al to preferentially form aluminum trichloride (AlCl₃) [See Refs. 1-3]. While this method does theoretically reduce reaction with the quartz enclosure material, it is worthwhile to mention that AlCl₃ still reacts with quartz components in the reactor, again resulting in oxygen and silicon contamination of the growing films. Additionally, this method suffers from extremely poor crystal quality at high growth rates, which restricts it to growth rates less than 16 μm/hr. In fact, high-quality films with mirror-like surfaces were only produced at a growth rate of 1.7 μml/hr on sapphire substrates [See Ref. 2]. Such a low growth rate provides no benefit over other growth techniques such as MBE or MOCVD, and makes this process impractical for thick film growth. More recently, the same group has reported smooth AlN growth on Si(111) substrates with growth rates up to approximately 16 μm/hr [See Ref. 4]. These growth rates, however, are still too low to efficiently produce thick AlN templates and free-standing layers in a manufacturing environment.

Bliss et al. have adopted a different approach utilizing a pre-reacted aluminum chloride amine adduct as the aluminum source [See Ref 5]. During growth the aluminum-containing adduct is heated to 250-360° C., which then reacts with ammonia to form AlN. Although this method does reduce reaction of AlCl₃ with the quartz tubing in the source zone, decomposition of the adduct in the growth zone will allow AlCl₃ to react with any exposed quartz surface, again resulting in contamination of the growing film. Furthermore, the authors also report the growth of high-quality films at growth rates of 5 μm/hr or less, which is impractical practical for thick film growth.

Despite the efforts of researchers to grow high-quality films, the growth of Al-containing III-nitride semiconductors by HVPE is still plagued by slow growth rates and mediocre crystal quality. To take full advantage of the capabilities of the HVPE process, higher growth rates and improved crystal quality, including lower impurity incorporation, is required. Once these objectives are achieved, the use of HVPE for the growth of Al-containing III-nitride compound semiconductors can be used for the production of thick template films and free-standing wafers for improved subsequent epitaxial device growth.

### SUMMARY OF THE INVENTION

To overcome the limitations in the prior art described above, and to overcome other limitations that will become apparent upon reading and understanding the present invention, the present invention discloses a superior method for growing III-nitride semiconductor crystals containing aluminum by hydride vapor phase epitaxy (HVPE). The method utilizes corrosion-resistant materials and coatings to permit the reaction of aluminum with hydrogen halides at temperatures above 700° C. without reaction of the halogenated aluminum gaseous species with the enclosure materials of the HVPE reactor system.

Previous efforts to grow aluminum-containing compounds by HVPE with source zone temperatures above 700° C. have been unsuccessful since appreciable quantities of an aluminum monohalide, typically aluminum monochloride (AlCl), are produced by the reaction between aluminum and the hydrogen halide. This aluminum monohalide has proven detrimental to the epitaxial growth process since it reacts with the quartz (SiO₂) enclosure material commonly used in HVPE systems. This reaction corrodes the quartz enclosure material, resulting in silicon and oxygen contamination of the growing film. The use of corrosion-resistant coatings and materials in the HVPE reactor as described in this invention, however, enables the formation of an aluminum monohalide in appreciable quantities at temperatures above 700° C., which can successfully be used for the growth of high-quality aluminum-containing III-nitride films and free-standing layers at high growth rates.

A method for growing III-nitride films containing aluminum using HVPE in accordance with the present invention comprises the use of corrosion-resistant materials in an area of an HVPE system, the area of the HVPE system containing the corrosion-resistant materials being an area that contacts an aluminum monohalide, aluminum dihalide, or aluminum trihalide, heating a source zone containing an aluminum source above a predetermined temperature, and growing the III-nitride film containing aluminum within the HVPE system containing the corrosion-resistant material.

Such a method further optionally includes the corrosion-resistant material being made from a material comprising preferably of refractory carbides and refractory nitrides, the corrosion-resistant material preferably being selected from a group consisting of boron nitride, silicon carbide, and tantalum carbide, the predetermined temperature being 700 degrees Centigrade or higher, the III-nitride film containing aluminum being an aluminum nitride film, the III-nitride film containing aluminum being grown at a rate faster than five microns per hour, and the III-nitride film containing aluminum being grown at a different temperature than the predetermined temperature. The invention further comprises a film or optoelectronic or electronic device grown using the method of the present invention.

### BRIEF DESCRIPTION OF THE DRAWINGS

Referring now to the drawings in which like reference numbers represent corresponding parts throughout:

FIG. 1 illustrates the equilibrium partial pressures of gaseous species over aluminum metal as a function of temperature.

FIG. 2 illustrates the equilibrium partial pressures of gaseous species over a mixture of aluminum and gallium metals as a function of temperature.

FIG. 3(a) illustrates a Nomarski optical contrast micrograph of an AlN film grown directly on a sapphire substrate using the method of the present invention, demonstrating the uniform and smooth surface morphology achieved with the present invention.

FIG. 3(b) illustrates a cross-sectional Scanning Electron Microscope (SEM) image of an AlN film revealing an internal crack in the AlN film.

FIGS. 4(a) and 4(b) are Nomarski optical contrast micrographs of an AlN film grown using HVPE in the related art [Ref. 5] demonstrating the rough and non-uniform surface morphology traditionally observed by HVPE grown AlN films.

FIG. 5 is a schematic diagram of an HVPE system that may be used for the growth of Al-containing III-nitride compound semiconductors according to the preferred embodiment of the present invention, wherein the thick lined regions of the diagram designate areas that should be made from materials and/or coatings that are corrosion-resistant.

FIG. 6 is a flow chart indicating the process steps used to grown III-nitrides films in accordance with the present invention; and

FIG. 7 is a flowchart illustrating the process steps performed in accordance with the preferred embodiment of the present invention.

### DETAILED DESCRIPTION OF THE INVENTION

In the following description of the preferred embodiment, reference is made to a specific embodiment in which the invention may be practiced. It is to be understood that other embodiments may be utilized and changes may be made without departing from the scope of the present invention.

Overview

The present invention describes materials and methods for growing III-nitride semiconductor crystals containing aluminum by hydride vapor phase epitaxy (HVPE). Al-containing III-nitride semiconductors are of interest since they have emerged as a viable means for fabricating optoelectronic devices and high-power, high-frequency electronic devices. Accordingly, the growth of Al-containing III-nitrides has been pursued by a variety of techniques, but the unavailability of bulk III-nitride crystals or lattice-matched substrates have resulted in heteroepitaxial films of poor quality, possessing high defect densities. One possible solution to this problem is to deposit thick Al-containing III-nitride films by hydride vapor phase epitaxy (HVPE). These thick films can be removed from their original substrates to form free-standing substrates, or used as template layers for improved epitaxial device layer growth. Efforts to produce thick Al-containing III-nitride films by HVPE, however, have been largely unsuccessful due to contamination issues resulting from using high source zone temperatures. Previous efforts to grow aluminum containing compounds by HVPE with source zone temperatures above 700° C. have been unsuccessful since appreciable quantities of an aluminum monohalide, typically aluminum monochloride (AlCl), are produced by the reaction between aluminum and the hydrogen halide at these higher temperatures. This aluminum monohalide has proven detrimental to the epitaxial process since it reacts with the quartz (SiO₂) enclosure material commonly used in HVPE systems. This reaction corrodes the quartz enclosure material, resulting in silicon and oxygen contamination of the growing film. The present invention solves this problem by utilizing corrosion-resistant materials and coatings to permit the reaction of aluminum with a hydrogen halide at temperatures above 700° C. without reaction of these reaction products with the enclosure materials of the HVPE reactor system. The use of corrosion-resistant coatings and materials in the HVPE reactor as described in this invention enables the formation of an aluminum monohalide in appreciable quantities at temperatures above 700° C., which can be successfully used for the growth of high-quality aluminum-containing III-nitride thick films and free-standing wafers at high growth rates.

According to the present invention, Al-containing III-nitride materials fabricated with high quantities of aluminum monohalides (e.g. aluminum chloride (AlCl)) are produced at faster growth rates with higher crystalline quality than these same materials produced by reactions with aluminum dihalides (e.g. aluminum dichloride (AlCl₂)) or aluminum trihalides (e.g. aluminum trichloride (AlCl₃)). Additionally, the reactor materials described in this invention will also enable the growth of Al-containing III-nitride compound semiconductors with low concentrations of oxygen and silicon impurities, both impurities of which are detrimental to overall crystal quality. These reactor materials are extremely valuable for corrosion-resistance against halogenated aluminum reactive species.

This invention solves the previous problems in growing Al-containing compound semiconductors with source zone temperatures above 700° C. for the preferential formation of aluminum monohalide. This temperature criterion combined with the use of reactor coatings and materials that are corrosion resistant enables the growth of high-quality Al-containing III-nitride compound semiconductor films and free-standing layers at high growth rates. Materials grown in this manner may be subsequently used for the growth of improved electronic and optoelectronic devices by a variety of growth techniques.

The present invention enables the production of high-quality compound semiconductor materials containing aluminum. The methods, processes, and procedures described relate to the growth of all semiconductor compounds containing aluminum (Al) and nitrogen (N). The invention is particularly suitable for III-nitride semiconductors of AlGaN or AlGaInN containing a high Al mole fraction, and even more suitable for pure AlN. Nevertheless, the invention relates to all layers that contain N and large mole fractions of Al, typically greater than 5% Al. Furthermore, the addition of other elements, for example for electronic doping as is known within the art, is also within the scope of this invention. Examples of such elements include, but are not limited to, silicon (Si), magnesium (Mg), germanium (Ge), beryllium (Be), calcium (Ca), iron (Fe), and nickel (Ni). The grown materials may contain combinations of the group III elements Al, gallium (Ga), boron (B), thallium (TI), and indium (In), and group V elements nitrogen (N), phosphorus (P), antimony (Sb), bismuth (Bi), and arsenic (As) in any composition and proportion. Accordingly, in the remainder of the document when the phrase “aluminum(Al)-containing III-nitride semiconductors” (or any derivates of this phrase) in this document refers to all compounds formed from elements in groups III and V of the periodic table of the elements, that also contain aluminum (Al) and nitrogen (N). Additionally, elements not in group III or group V may be added to the growing film, and the addition of these elements is still within the scope of this invention. For example, a refractory metal may be added to the growing film.

Technical Description

The present invention provides a method and materials for the fabrication of Al-containing III-nitride semiconductor films and free-standing wafers or substrates by HVPE. Film growth is accomplished using conventional metal-source HVPE involving the reaction of a halide compound, such as but not limited to gaseous hydrogen chloride (HCl), with a metal source containing aluminum. The metal source may consist of pure aluminum or it may consist of a mixture of elements that includes aluminum, for example gallium and aluminum, or aluminum and magnesium. The source material may contain aluminum in any composition or proportion. The source material is heated to a temperature above 700° C. to facilitate reaction between the halide compound and the metal source to form halogenated aluminum products, principally AlCl and AlCl₃. The halogenated products of aluminum are then transported to the growing film by a carrier gas, typically nitrogen, hydrogen, helium, or argon, or combinations of these gases. Use of alternate carrier gases does not fundamentally deviate from the scope of the present invention. During transport to the substrate, at the substrate, or in the exhaust stream, the Al-containing chloride will react with the group V source, typically ammonia (NH₃), to form the Al-containing film. The term “film” will be used interchangeably in this document with the terms “layer”, “material”, and “product”, which all refer to the grown Al-containing III-nitride crystalline material.

According to the present invention, the source zone, which contains the Al source material, is heated to a temperature above 700° C. The source material is then preferentially reacted with gaseous HCl, but reaction is not limited to this gas. The halogenated aluminum products may be formed from reaction of aluminum with any halogenated hydrogen, including (but not limited to) hydrogen chloride, hydrogen bromide, or hydrogen iodide. At temperatures above 700° C. there are primarily three possible reactions that take place when the halide source is HCl, as outlined in chemical equations 1, 2, and 3:
2Al(l)+2HCl(g)→2AlCl(g)+H₂(g) (Chemical Equation 1)
Al(s)+2HCl(g)→AlCl₂(g)+H₂(g) (Chemical Equation 2)
2Al(s)+6HCl(g)→2AlCl₃(g)+3H₂(g) (Chemical Equation 3)

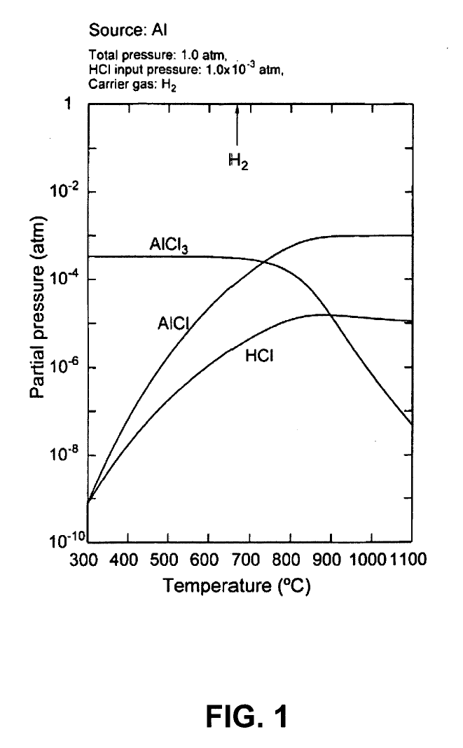

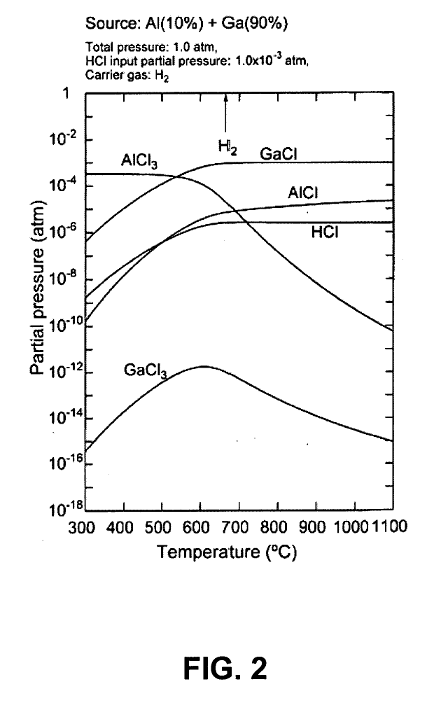

A thermodynamic analysis performed by Kumagai et al. which can be found in United States Patent Publication No. 20050166835 [Ref. 3], determined that at temperatures above 700° C., aluminum monochloride (AlCl) quickly becomes the dominant halogenated aluminum product when the source is composed of only aluminum. As the source temperature is increased, the partial pressure of the AlCl greatly surpasses that of AlCl₃. The presence of AlCl₂ is often neglected since its partial pressure is usually well below that of AlCl and/or AlCl₃ over the temperature range of interest. The results of the thermodynamic analysis are depicted in FIG. 1 in the patent publication by Kumagai et al. [Ref. 3] and the figure is reproduced here for convenience. Additionally, further analysis in the same patent application determined that for a mixed source of aluminum and gallium, AlCl increasingly became the dominant halogenated aluminum product above 700° C., which is consistent with the results from the pure aluminum source analysis. This result is depicted in FIG. 2 in the patent publication Kumagai et al. [Ref. 3] and is reproduced here for convenience.

According to the present invention, the source zone for the aluminum source is maintained at a temperature above 700° C. in order to produce a reactant stream containing significant amounts of the monohalogenated aluminum reactive species, typically AlCl. The present inventors have discovered that the presence of this monohalogenated aluminum reactive species in significant amounts improves the crystal quality of Al-containing III-nitride compound semiconductors. As a result of the materials utilized in the reactor, which are described later as a part of this invention, the present inventors were able to successfully perform many experimental growths demonstrating that high-quality Al-containing materials could be produced at high growth rates when the source zone temperature was maintained above 700° C. This result was not obvious prior to this invention since researchers have been unable to grow at source zone temperatures above 700° C.; the significant amounts of AlCl produced at these temperatures strongly react with the quartz components commonly used in HVPE reactors. In fact, previous growth efforts have been almost exclusively limited to source zone temperatures of 500° C. or below to prevent the formation of the AlCl product, which this invention has determined is necessary for high-quality growth of Al-containing III-nitride films at high growth rates.

After reaction of the aluminum source with the halogenated hydrogen in the source zone at temperatures above 700° C., film growth may occur at any temperature exceeding 500° C. However, the inventors have found that growth zone or substrate temperatures in excess of 1000° C. are preferable, and growth zone or substrate temperatures in excess of 1200° C. are most preferable to yield high quality Al-containing III-nitrides. The present inventors have demonstrated the growth of an Al-containing III-nitride compound semiconductor, specifically aluminum nitride (AlN), to prove the effectiveness of the present invention. AlN films were heteroepitaxially deposited by HVPE on sapphire substrates utilizing the concepts in this invention. The resulting single-crystalline AlN films are of the highest quality known to date grown by HVPE at growth rates above 5 μm/hr. The AlN films were deposited at growth rates up to 75 μm/hr on c-plane sapphire substrates and were optically transparent, a first for the growth of AlN at such high growth rates. The surfaces of the films are also specular and relatively uniform.

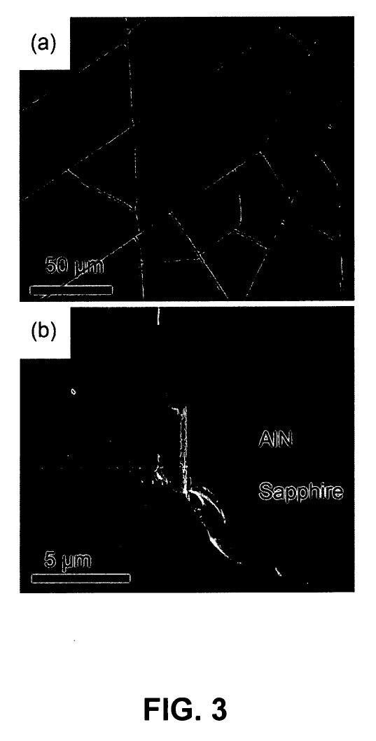

FIG. 3(a) shows a Nomarski optical contrast micrograph of one such film grown on a sapphire substrate. Cracking within the AlN films is observed in this image, however, these cracks were found to be subsurface cracks which subsequently ‘healed’ (closed) with further deposition. Accordingly, these cracks have no impact on the utility of these films as template layers for further device-layer growth.

FIG. 3(b) shows a cross-sectional scanning electron microscopy (SEM) image of one such crack. The SEM analysis indicates that the subsurface cracks and are only present within the first few microns of the AlN layers. Instead of propagating upward through the film, the cracks are healed by lateral overgrowth. This behavior was observed for all cracks present in our AlN films. Furthermore, atomic force microscopy (AFM) analysis confirmed that the cracks did not adversely affect the film surfaces. The AFM analysis indicated a root-mean-square (rms) roughness of 0.316 nm over 5×5 μm sampling areas, indicating that the surfaces of the AlN films were very smooth.

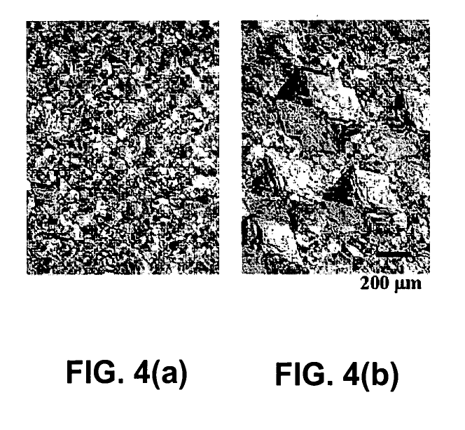

In comparison, FIGS. 4(a) and 4(b) are Nomarski optical micrographs of AlN films that show the surface morphology of AlN films exhibited in Bliss et al. [Ref. 5], demonstrating the roughness and non-uniformity that AlN films commonly possess when grown by HVPE. These results were obtained by utilizing an aluminum chloride amine adduct as the aluminum source (as described in the “Description of Related Art” section of this application), which was motivated by the desire to avoid the strong reactivity of the aluminum chloride reaction products with the quartz HVPE reactor components.

The crystalline quality of the AlN films grown by the present inventors at high growth rates is comparable to, if not superior to, the highest-quality films grown by HVPE at low growth rates reported in the literature. Typical full widths at half-maximum (FWHM) of X-ray rocking curve measurements for the AlN films grown according to the present invention are 310-640 arcsec for the on-axis 0002 peak and 630-800 arcsec for the off-axis 2021 peak. To further analyze the structural quality of the films, transmission electron microscopy (TEM) analysis was performed. This analysis determined that the threading dislocation density was ˜2×10⁹ cm⁻², and the details of this analysis can be found in Appendix A of the parent U.S. Provisional Patent Application Ser. No. 60/798,905, set forth in the Cross-Reference of Related Applications above.

A secondary ion mass spectrometry (SIMS) analysis was also performed on the AlN films to determine the impurity incorporation. The concentration of silicon in particular was analyzed to determine whether or not unintentional silicon incorporation had been suppressed. The results of this analysis indicated that the silicon concentration in the films was below 10¹⁸ atoms/cm³, and typically ranged between 2.16×10¹⁷ atoms/cm³ and 9.41×10¹⁷ atoms/cm³. These values were very close to the SIMS equipment low detection limits, indicating that silicon contamination did not occur.

These growth results represent substantial progress towards the mass production of Al-containing III-nitride substrates. Previous attempts to grow Al-containing III-nitride thick films by HVPE have been plagued by poor crystal quality and/or extremely slow growth rates, which effectively make growth of these compounds by HVPE of little value [See Refs. 2 and 4-7]. The present invention, however, has overcome these difficulties and succeeded in making HVPE growth of high-quality Al-containing III-nitride semiconductor films and free-standing layers at high growth rates possible.

The crystals grown according to the present invention may be of various sizes. The crystals preferably have dimensions of at least 5 mm×5 mm×0.5 μm. Any or all of these dimensions may be larger in value. Additionally, the total volume of the crystal may also be larger. Large crystals may be fabricated using the methods, materials, and procedures described in this document. For example, bulk AlN crystals may be fabricated with diameters larger than 2 inches. These crystals may be grown for sufficient time to produce large boules containing lengths in excess of 2 inches.

An equally important part of this invention is the choice of materials used in the HVPE reactor. The present invention provides materials that enable the formation and transport of halogenated aluminum products without reaction of these products with the enclosure materials of the HVPE reactor system. The materials described in this invention provide a substantial improvement over state-of-the-art materials used in HVPE reactors. Currently, HVPE reactors predominantly utilize quartz reaction vessels, tubing, and various components of other geometries to contain, guide, and manipulate halogenated aluminum gaseous species. Although perceived as economical, the use of quartz components is detrimental to the growth of Al-containing III-nitride compound semiconductors since the halogenated aluminum products, which are typically a combination of AlCl and AlCl₃, strongly react with the quartz components. These reactions cause oxygen and silicon contamination of the growing crystal, resulting in films of poor quality with high impurity concentrations. The present invention avoids these problems by using corrosion-resistant coatings and materials that are able to contain and transport halogenated aluminum species while avoiding reaction with quartz materials.

According to this invention, the use of the following materials as coatings, protective plates, bulk components and/or any other means of containing and/or guiding the source materials and/or reactant gases is effective in preventing detrimental reactions with halogenated aluminum species. We have experimentally determined that coatings of boron nitride, silicon carbide, and tantalum carbide are resistant to corrosion by halogenated aluminum products in the temperature ranges optimal for growth of Al-containing III-nitride films. Other suitable coatings include refractory carbides and nitrides of a variety of metals, including but not limited to the following: silicon, niobium, zirconium, tantalum, tungsten, titanium, vanadium, chromium, nickel, molybdenum, rhenium, and hafnium. These materials may be used to coat all surfaces within the reactor to prevent unwanted corrosion. They may be used to coat any bulk material, but are especially suitable for coating graphite components. The coating materials described previously are also effective in the form of protective plates, crucibles, tubes, and other geometries, many of which have been utilized by the present inventors. Components in these forms have been shown to successfully contain and/or guide the source materials and halogenated aluminum species. Also, experiments indicate that high-purity metal alloys containing high concentrations of tantalum, molybdenum, titanium, nickel, chromium, rhenium, and/or niobium are corrosion-resistant and thermally stable, and therefore, when used in any form (e.g. bulk, plate, tube, coating) are suitable for use in HVPE growth of Al-containing III-nitride semiconductors. Many of the materials were utilized when growing the previously mentioned AlN films, demonstrating their effectiveness for the growth of Al-containing III-V semiconductors.

It should further be noted that it is not necessary to completely exclude materials that are chemically attacked by Al monohailide or Al trihalide from HVPE growth system design in the practice of this invention. However, the use of such less stable materials should preferably be confined to regions in the growth system in which the corrosion products are unlikely to be transported into the general vicinity of the growing III-nitride material. For example, quartz tubes may be used to transport gases to the general vicinity of the source zone, up to which point no Al monohalide or Al trihalide is expected to be present. However, the presence of quartz components between the source zone and the growing III-nitride material would be ill-advised because of the increased likelihood of chemical attack and hence impurity incorporation in the growing III-nitride material.

In summary, the present invention describes a method for growing crystals of Al-containing III-nitride compound semiconductors with a step that involves reacting pure aluminum, or a mixture of sources that includes aluminum, with a halogenated hydrogen at temperatures above 700° C. to produce a gaseous halogenated species. This invention also describes the materials needed to successfully contain and/or guide the halogenated product, without reaction of the source gases with the reactor components and also without contamination of the growing film. The present invention is particularly suitable for HVPE growth of Al-containing III-nitride semiconductors.

A process utilizing an HVPE system will now be described for the vapor-phase epitaxial growth of Al-containing III-nitride semiconductors adhering to the concepts of the present invention. The described process is one example of a growth process that makes use of the present invention, but similar procedures may also be effective. The present invention may be embodied in other forms that still maintain the essential characteristics and ideas of this invention. Of central importance to this invention is the use of an aluminum source zone or a growth zone with a temperature above 700° C. and the use of corrosion-resistant coatings and/or bulk materials to avoid reactions with aluminum halides in the reactor. Consequently, the following description is not meant to limit the scope of this invention, but instead, to illustrate one example of its application.

The growth apparatus used for the growth of the Al-containing III-nitride can be any vapor-phase epitaxial growth system that is capable of carrying hydride and halide reactive species, typically separately. The reactor can be of any geometry, for example of horizontal or vertical orientation. The system should also employ a heater or preferably multiple heaters that are able to precisely control the temperature profile in the reactor. These heaters may be located internally or externally with respect to the reactor, with combinations of both readily achievable. The method of heating, for example resistive elements or radio-frequency induction, is not critical to the present invention. Ideally, one heater will control the source zone temperature and another the growth zone temperature. There should also be a space inside the reactor to place the group III source materials. However, the use of pre-reacted metal halide source materials, such as AlCl₃, is equally compatible with the present invention as long as these reactants are heated above 700° C. at some point during the growth process.

Prior to beginning the growth process, the reactor must be prepared so that there are few or no exposed quartz surfaces likely to contact the group III-halide reactants upstream of the growing III-nitride material. This involves coating all possible components that are exposed to aluminum halides with one of the previously identified corrosion-resistant materials; alternately plates, tubes, and/or bulk components may perform the same task. It is important that all surfaces in the source zone, where the aluminum halide is formed, and all surfaces downstream from the source zone are coated and/or principally made from one of the corrosion-resistant materials.

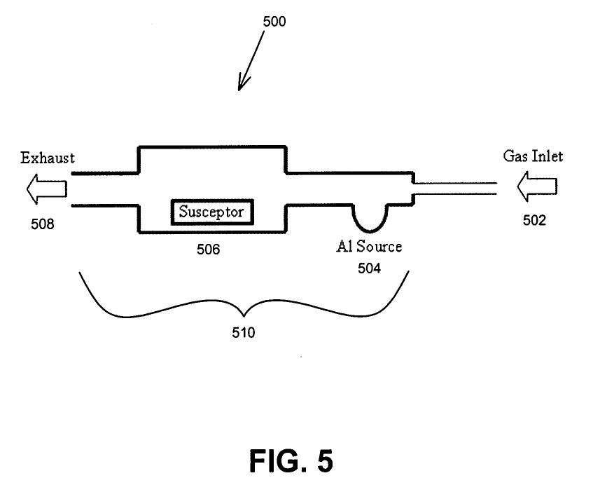

FIG. 5 illustrates an HVPE reactor 500 that may be used for the growth of Al-containing III-nitride compound semiconductors according to the preferred embodiment of the present invention, and that should be corrosion-resistant as described herein. The HVPE reactor 500 includes a gas inlet 502, an Al source 504 in a source zone, a susceptor 506 or plate in a growth zone on which a substrate may be heated during film deposition steps, and an exhaust 508. The thick lined regions of the HVPE reactor 500 encompassed by 510 designate areas that should be made from materials and/or coatings that are corrosion-resistant, as described herein.

After preparation of the reactor 500 with corrosion-resistant materials, any group III-nitride compound semiconductor film may be grown. The steps for producing an AlN film in accordance with the present invention will now be described, but this is an example of only one of the many film compositions that can be produced utilizing the present invention. Other Al-containing III-nitride films may just as easily be grown using similar procedures, including but not limited to compounds such as AlGaN, InAlGaN, and InAlGaAsN, where the molar fraction of each element may vary from 0 to 1.

After the reactor 500 is prepared with the corrosion-resistant materials, the substrate is placed in the growth zone, typically on a susceptor 506 (though a susceptor 506 is not specifically required for the practice of the present invention), and preferably the aluminum-containing source material 504 is placed in the source zone. The aluminum-containing source material 504 is preferably held in a source boat, where the term “boat” simply refers to an object that is capable of holding solid or molten source material. The boat can be of a variety of forms. For example, the boat could be a box without a top face, or a portion of a tube with an outer diameter that is slightly smaller than the dimension of the corresponding source tube. Additionally, there can be one or more aluminum sources 504 in one or more source tubes. Alternatively, the source material 504 can be placed in the source zone without the use of a separate boat. The method of placing the aluminum source 504 in the source zone is not critical to this invention. The material can either be placed in the source zone 504 prior to the growth process, or be delivered to the growth zone during growth, as with the use of pre-reacted metal halide gaseous precursors such as AlCl₃. The critical part of this invention is that the source material 504 is in the source zone at some point during the growth process, where the temperature of the source material 504 can then be controlled. Additionally, the source zone may be located in the same vicinity as, or within, the growth zone.

The reactor 500 is then filled with a carrier gas such as hydrogen, nitrogen, argon, or helium. The choice of gas is not important to the present invention. In fact, any gas or combination of gases can be used without deviating from the present invention. For example, the reactor 500 can be filled with a combination of a carrier gas and ammonia. The principle purpose of the carrier gas is to establish a stable pressure in the reactor 500. The reactor 500 may be maintained at any pressure between 0.01 and 1500 torr, but is typically in the range of 10-800 torr.

The growth zone is then heated to the desired growth temperature, preferably in the range of 500-1800° C. The upper limit for the growth zone temperature is not important for the present invention and may be heated to any achievable temperature. The source zone is also heated to a temperature of 700° C. or above, according to the present invention. If more than one source zone is used for the aluminum-containing source material(s) 504, each of these source zones should be heated to 700° C. or above.

After the temperature(s) in the reactor 500 stabilize, a reactive halide species, typically HCl, is delivered to the growth zone. A carrier gas is often used to transport the HCl gas to the source zone, and is commonly hydrogen, nitrogen, argon, or helium, but the use of a carrier gas is not necessary. Once the HCl reaches the aluminum-containing source material 504, reaction occurs and one or more aluminum chlorides are formed. An alternative way to create these chlorides is to use pre-reacted metal halide source materials 504, such as gaseous AlCl₃, and deliver these source materials to the growing film via the source zone. The source of the aluminum chlorides is not critical to the present invention. The key consideration is simply that aluminum halides are present in the source zone, where they can be heated to a temperature of 700° C. or above.

The aluminum chlorides are then delivered to the growth zone using the same carrier gas mentioned previously. While a carrier gas is often used, it is not required for the present invention. It is simply a means of controlling the flow of the reactants and reactor pressure, but this could be equally well accomplished without the use of a carrier gas by controlling the flow of the reactive halide species and/or the pre-reacted metal halide source material.

Ammonia gas is also separately delivered to the growth zone. The use of a carrier gas to facilitate flow control is again optional. The ammonia gas combines with the aluminum chloride(s) to form AlN, preferably on a substrate in the growth zone. After growth is complete, the reactor 500 is cooled and the AlN film is removed from the reactor 500.

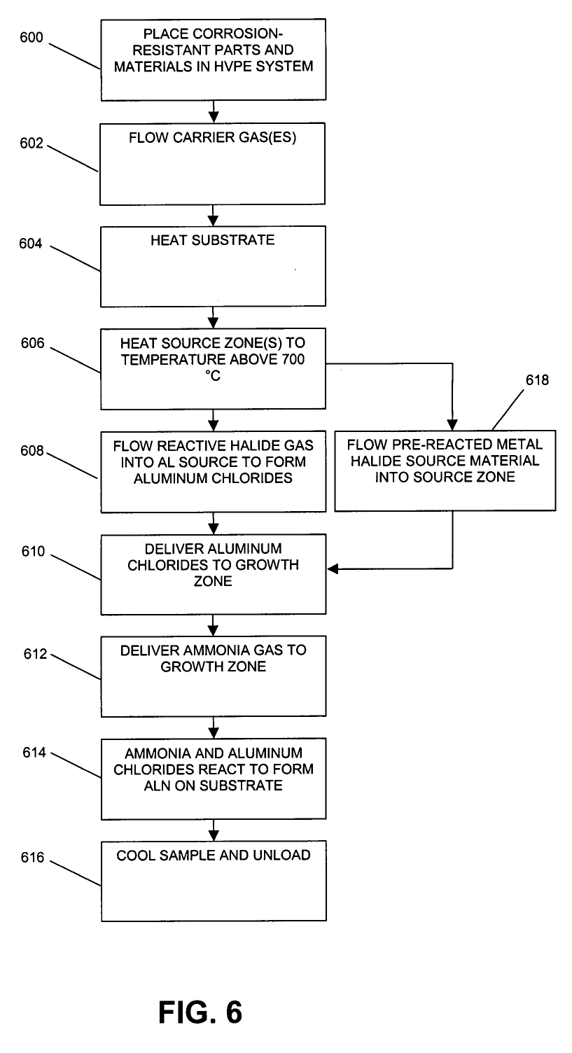

This growth procedure is summarized in a flow chart in FIG. 6, wherein Block 600 represents the step of placing the corrosion-resistant parts and materials in the HVPE system, Block 602 represents the step of flowing the carrier gas(es), Block 604 represents the step of heating the substrate, Block 606 represents the step of heating the source zone(s) of the HVPE system to a temperature above 700° C., Block 608 represents the step of flowing reactive halide gas into the Al source to form aluminum chlorides, Block 610 represents the step of delivering the aluminum chlorides to the growth zone of the HVPE system, Block 612 represents the step of delivering ammonia gas to the growth zone of the HVPE system, Block 614 represents the ammonia and aluminum chlorides reacting to form AlN on the substrate, and Block 616 represents the step of cooling the sample and unloading it from the HVPE system.

Block 618 represents an alternate step of flowing pre-reacted metal halide source material into the source zone of the HVPE system. This alternate step may be used in place of Block 608, and depicts another means for forming the reactive aluminum halide species.

It is worthwhile to note that the aluminum halide can be formed by any means, and two have been described in this section. These two means can be used collectively or separately to achieve the goal of supplying aluminum source material(s) for growth. Additionally, the flow chart shows one example growth procedure and is by no means intended to limit the scope of the invention. Variations on this approach are still within the scope of this invention. For example, the Group V source (NH₃) may be delivered to the growth zone before, after, or at the same time as the delivery of the Group III source. Or, the grown material does not have to be cooled prior to removing it from the reactor.

This basic growth procedure has been demonstrated for AlGaN films. By changing the composition and/or number of group III sources or the group V sources and their corresponding flow rates, a variety of different Al-containing III-nitride semiconductor films can be grown according to this invention.

Process Steps

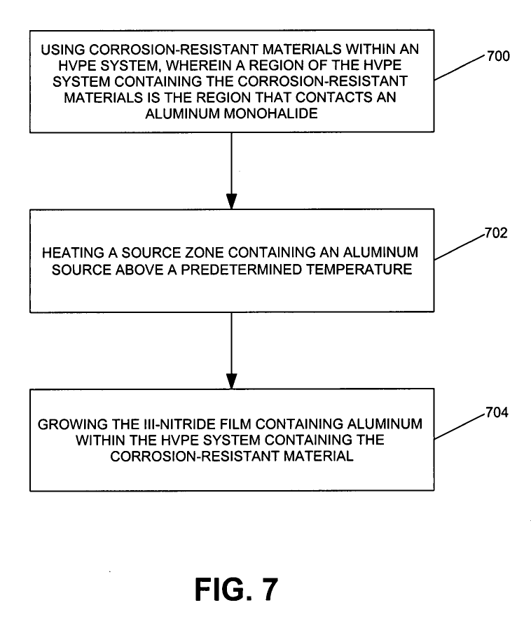

FIG. 7 illustrates the process steps of the preferred embodiment of the present invention.

Box 700 illustrates the use of corrosion-resistant materials within an HVPE reactor, wherein an area of the HVPE reactor containing the corrosion-resistant materials is an area that contacts an aluminum halide compound.

Box 702 illustrates heating a source zone of the HVPE reactor containing an aluminum source above a predetermined temperature.

Box 704 illustrates growing the III-nitride film containing aluminum within the HVPE reactor containing the corrosion-resistant material.

Modifications and Variations

Although the growth of AlN was described in this patent application, the growth of any Al-containing III-V compound semiconductor may be possible with the present invention, particularly those containing high mole fractions of aluminum. Moreover, any compound containing aluminum which may be formed using the reaction of an aluminum source with a hydrogen halide will benefit from this invention.

Film growth in the present invention uses metal-source hydride vapor phase epitaxy (HVPE). Any derivatives of this technique, however, are still within the scope and spirit of this invention.

The source material used in the source zone may contain Al, a combination of Al with other elements, or any other aluminum-containing compound that can be used to form a halogenated product of aluminum. Examples include (but are not limited to):

1. mixed aluminum sources containing group III elements of B, Ga, In, and/or Tl,

2. mixed aluminum-containing sources containing any element or elements other than aluminum,

3. Al-containing adducts such as AlClₓ:(NH)_{y}, and

4. Al-containing compounds that can decompose and/or react to yield a halogenated aluminum product.

The source material can also consist of pre-reacted metal halide source materials, such as AlCl₃, which can be delivered to the source zone and then heated. Furthermore, the inventors' research on the growth of Al-containing III-nitride films has established that simple modifications of the process will allow the technique to be adapted for film growth by metalorganic chemical vapor deposition (MOCVD).

The reactor materials used in this invention, which include boron nitride, silicon carbide, tantalum carbide, an assortment of refractory carbide and refractory nitrides, and a variety of pure refractory metals and metal alloys containing tungsten, tantalum, molybdenum, nickel, chromium, and niobium, may be used in any combination and/or form (e.g, coating, plate, tube, bulk geometrical shape) as an anti-corrosive, protective material. Additionally, any compositional variant of these materials that includes significant quantities of said materials will also serve the same function. Other related materials may be suitable for use in reactor components for the growth of Al-containing III-V semiconductors which were not explicitly described, but are still within the scope and spirit of this invention.

Advantages

The present invention allows for the development of completely new products, in particular for aluminum-containing III-nitride semiconductors. For example, the present invention would enable the production of high-quality, single-crystal AlN and AlGaN films and free-standing wafers. At present these products are not readily available, and could be used for the subsequent growth of improved electronic and optoelectronic devices, especially those emitting in the ultraviolet region of the electromagnetic spectrum. Therefore, the present invention allows for the development of Al-containing II-nitride semiconductor substrates, which may be of sufficient dimensions to allow re-growth of electronic or optoelectronic semiconductor devices.

Other advantages include:

1. the growth of high-quality, single-crystalline Al-containing III-nitride compounds at growth rates in excess of 5 μm/hr, which fully utilizes the potential of the HVPE growth technique for thick III-nitride films and free-standing wafers;

2. the growth of Al-containing compounds using significant amounts of aluminum halide precursors;

3. the use of corrosion-resistant coatings and materials which are non-reactive with aluminum halides, including but not limited to AlCl, AlCl₂, and AlCl₃;

4. Al-containing III-nitride compounds with low oxygen and silicon incorporation due to the absence of reaction of halogenated aluminum species with quartz reactor components;

5. the growth of Al-containing III-nitride semiconductors without corrosion of the quartz hardware utilized in HVPE reactors; and

6. the ability to grow high quality Al-containing nitrides at growth temperatures in excess of 700° C., and more preferably at growth zone temperatures in excess of 1200° C.

Previous growth techniques and materials were unable to accomplish these objectives.

Appendices

Further information on the present invention can be found in the Appendices of the parent U.S. Provisional Patent Application Ser. No. 60/798,905, set forth in the Cross-Reference of Related Applications above, wherein the Appendices are entitled “Direct Heteroepitaxial Growth of Thick AlN Layers on Sapphire Substrates by Hydride Vapor Phase Epitaxy” (Appendix A) and “Growth of Thick AlN Layers on Sapphire Substrates by Hydride Vapor Phase Epitaxy” (Appendix B), which Appendices are incorporated by reference herein.

Moreover, Appendix A was later published as: Derrick S. Kamber, Yuan Wu, Benjamin A. Haskell, Scott Newman, Steven P. DenBaars, James S. Speck, and Shuji Nakamura, “Direct heteroepitaxial growth of thick AlN layers on sapphire substrates by hydride vapor phase epitaxy,” Journal of Crystal Growth 297 (2006)321-325, on Nov. 22, 2006, which publication is incorporated by reference herein.

### REFERENCES

The following references are incorporated by reference herein:

[1] Y. Kumagai, T. Yamane, T. Miyaji, H. Murakami, Y. Kangawa, A. Koukitu, Phys. Stat. Sol. (c) 0, No. 7, 2498-2501 (2003).

[2] Y. Kumagai, T. Yamane, A. Koukitu, J. Crystal Growth 281, 62-67 (2005).

[3] United States Patent Publication Number 20050166835.

[4] Y. Kumagai, T. Nagashima, A. Koukitu, Jpn. J. Appl. Phys. 46, L389 (2007).

[5] D. F. Bliss, V. L. Tassev, D. Weyburne, J. S. Bailey, J. Crystal Growth 250 (2003) 1-6.

[6] Y. Yamane, H. Murakami, Y. Kangawa, Y. Humagai, A. Koukitu, Phys. Stat. Sol. (c) 2, No. 7, (2005) 2062-2065.

[7] O. Ledyaev, A. Cherenkov, A. Nikolaev, I. Nikitina, N. Kuznetsov, M. Dunaevski, A. Titkov, V. Dmitriev, Phys. Stat. Sol. (c) 0 O, No. 1, (2002) 474-478.

### CONCLUSION

This concludes the description of the preferred embodiment of the present invention. The foregoing description of one or more embodiments of the invention has been presented for the purposes of illustration and description. It is not intended to be exhaustive or to limit the invention to the precise forms disclosed. Many modifications and variations are possible in light of the above teaching. It is intended that the scope of the invention be limited not by this detailed description, but rather by the claims appended hereto.

What is claimed is:

1. A method for growing a III-nitride film containing aluminum using Hydride Vapor Phase Epitaxy (HVPE), comprising:
using one or more corrosion-resistant materials in the HVPE reactor, wherein a region of the HVPE reactor containing the corrosion-resistant materials is a region that contacts an aluminum halide;
heating a source zone of the HVPE reactor containing an aluminum-containing source at or above a predetermined temperature; and
growing the III-nitride film containing aluminum within the HVPE reactor containing the corrosion-resistant materials.

2. The method of claim 1, wherein the corrosion-resistant material is made from a material comprising refractory carbides, including carbides of silicon, niobium, tantalum, zirconium, tungsten, titanium, vanadium, nickel, chromium, molybdenum, rhenium, and/or hafnium.

3. The method of claim 1, wherein the corrosion-resistant material is made from a material comprising refractory nitrides, including nitrides of silicon, niobium, tantalum, zirconium, tungsten, titanium, vanadium, nickel, chromium, molybdenum, rhenium, and/or hafnium.

4. The method of claim 1, wherein the corrosion-resistant material is selected from a group consisting of boron nitride, silicon carbide, and tantalum carbide.

5. The method of claim 1, wherein the corrosion-resistant material is selected from a group containing high-purity alloys with high concentrations of tantalum, nickel, chromium, rhenium, molybdenum, titanium, and/or niobium.

6. The method of claim 1, wherein the predetermined temperature is 700 degrees Centigrade.

7. The method of claim 1, wherein the III-nitride film containing aluminum is an aluminum nitride film.

8. The method of claim 1, wherein the III-nitride film containing aluminum is grown at a rate faster than five microns per hour.

9. The method of claim 1, wherein III-nitride film containing aluminum is grown at a different temperature than the predetermined temperature.

10. The method of claim 1, wherein the III-nitride film containing aluminum has a silicon concentration below 10¹⁹ atoms/cubic centimeter.

11. The method of claim 1, wherein the III-nitride film containing aluminum is grown with an aluminum monohalide.

12. The method of claim 1, wherein the III-nitride film containing aluminum is doped with silicon, germanium, carbon, magnesium, beryllium, calcium, iron, cobalt, or manganese, either singly or in combination with one another.

13. The method of claim 1, wherein the III-nitride film is grown within a region of the HVPE reactor containing the corrosion-resistant materials.

14. The method of claim 1, wherein the corrosion-resistant material is in the form of a coating and is used to coat component surfaces of the HVPE reactor.

15. The method of claim 1, wherein the corrosion-resistant material is in the form of a bulk geometrical shape, such as a plate, tube, crucible, or other suitable geometrical shape.

16. The method of claim 1, wherein the growing step is performed at a temperature is in excess of 700° C.

17. The method of claim 16, wherein the growing step is performed at a temperature between 1200° C. and 1800° C.

18. The method of claim 1, further comprising, after the III-nitride film containing aluminum has been grown, growing one or more electronic or optoelectronic semiconductor device layers on the III-nitride film containing aluminum.

19. The method of claim 18, wherein the step of growing the device layers on the III-nitride film containing aluminum includes doping the device layers with n-type and p-type dopants, and growing one or more quantum wells in a re-growth layer on or below the doped device layers.

20. The method of claim 19, further comprising fabricating a light emitting diode or laser diode from the device layers.

21. The method of claim 1, wherein the III-nitride film contains one or more additional elements.

22. The method of claim 1, wherein the III-nitride film has dimensions of at least 5 mm×5 mm×0.5 μm.

23. A film grown using the method of claim 1.

24. A semiconductor device grown on top of a film grown using the method of claim 1.

25. An aluminum containing III-nitride film grown using an aluminum monohalide.

26. A method for growing a film containing aluminum using Hydride Vapor Phase Epitaxy (HVPE), comprising:
using one or more corrosion-resistant materials in the HVPE reactor, wherein a region of the HVPE system containing the corrosion-resistant materials is a region that contacts an aluminum halide;
heating a source zone of the HVPE reactor containing an aluminum-containing source at or above a predetermined temperature; and
growing the film containing aluminum within the HVPE reactor containing the corrosion-resistant materials.

27. The method of claim 26, wherein the predetermined temperature is 100 degrees Centigrade.
